(19) United States
(12) Patent Application Publication
(10) Pub. No.: US 2018/0277400 A1
(43) Pub. Date: Sep. 27, 2018

(54) SEMICONDUCTOR MANUFACTURING APPARATUS

(71) Applicant: TOSHIBA MEMORY CORPORATION, Minato-ku (JP)

(72) Inventor: Fumiki AISO, Kuwana (JP)

(73) Assignee: TOSHIBA MEMORY CORPORATION, Minato-ku (JP)

(21) Appl. No.: 15/699,222

(22) Filed: Sep. 8, 2017

(30) Foreign Application Priority Data
Mar. 23, 2017 (JP) 2017-058131

(51) Int. Cl. H01L 21/67; C23C 16/455; C23C 16/52; C23C 16/46

(52) U.S. Cl. CPC H01L 21/67017; H01L 21/67201; C23C 16/46; C23C 16/52; C23C 16/45544

(57) ABSTRACT

According to an embodiment, a semiconductor manufacturing apparatus includes a process chamber, a load lock chamber, a gas purge mechanism and a movement mechanism. The process chamber treats a substrate using process gas in a vacuum state. The load lock chamber temporarily houses the substrate while holding the vacuum state. The gas purge mechanism is in the process chamber or the load lock chamber. The movement mechanism retains the substrate below the gas purge mechanism. The gas purge mechanism includes a plurality of gas feed ports opposing to the movement mechanism and to eject inactive gas at a first pressure higher than an atmospheric pressure, and a plurality of gas discharge ports provided alternately along with the plurality of gas feed ports along a movement direction of the movement mechanism and to discharge the process gas and the inactive gas at a second pressure lower than the atmospheric pressure.

### CROSS-REFERENCE TO RELATED APPLICATIONS

This application is based upon and claims the benefit of priority from Japanese Patent Application No. 2017-058131, filed on Mar. 23, 2017; the entire contents of which are incorporated herein by reference.

### FIELD

Embodiments of the present invention relate to a semiconductor manufacturing apparatus.

### BACKGROUND

Semiconductor treats such as ALD (Atomic Layer Deposition) and CDE (Chemical Dry Etching) are generally performed in a process chamber in a vacuum state. In such semiconductor treats, there is a case where inactive gas is used in order to remove process gas sticking into holes and slits provided in a substrate. In this case, when the pressure of the inactive gas is low, there is a possibility that process gas that sticks into holes and slits large in aspect ratio (ratio between the diameter and the depth) is not sufficiently removed.

When a pressure in the process chamber is to be raised in order to feed high pressure inactive gas, this will take much time depending on the capacity of the process chamber.

According to present embodiments, there is provided a semiconductor manufacturing apparatus capable of enhancing a discharge effect of gas in a short time.

### BRIEF DESCRIPTION OF THE DRAWINGS

FIG. 1 is a diagram showing a schematic configuration of a semiconductor manufacturing apparatus according to a first embodiment;

FIG. 2 is a diagram briefly showing the inside of a load lock chamber;

FIG. 3 is a cross-sectional view taken along the sectional line A-A shown in FIG. 2;

FIG. 4 is a view of a gas purge mechanism as seen from its bottom face;

FIG. 5A is a cross-sectional view having a part of a substrate 100 expanded;

FIG. 5B is a cross-sectional view showing a state after the state shown in FIG. 5A;

FIG. 5C is a cross-sectional view showing a state after the state shown in FIG. 5B;

FIG. 6A is a cross-sectional view having parts of a gas purge mechanism and a movement mechanism expanded;

FIG. 6B is a cross-sectional view showing a state after the state shown in FIG. 6A;

FIG. 6C is a cross-sectional view showing a state after the state shown in FIG. 6B;

FIG. 7 is a diagram showing a schematic configuration of a semiconductor manufacturing apparatus according to modification 1;

FIG. 8 is a cross-sectional view showing a structure of a gas purge mechanism according to modification 2;

FIG. 9 is a view of a gas purge mechanism according to Modification 3 as seen from its bottom face;

FIG. 10 is a perspective view schematically showing a gas purge mechanism and a movement mechanism according to modification 3;

FIG. 11 is a diagram schematically showing a semiconductor manufacturing apparatus according to a second embodiment; and

FIG. 12 is a view of a gas purge mechanism according to the second embodiment as seen from its bottom face.

### DETAILED DESCRIPTION

Embodiments will now be explained with reference to the accompanying drawings. The present invention is not limited to the embodiments.

### First Embodiment

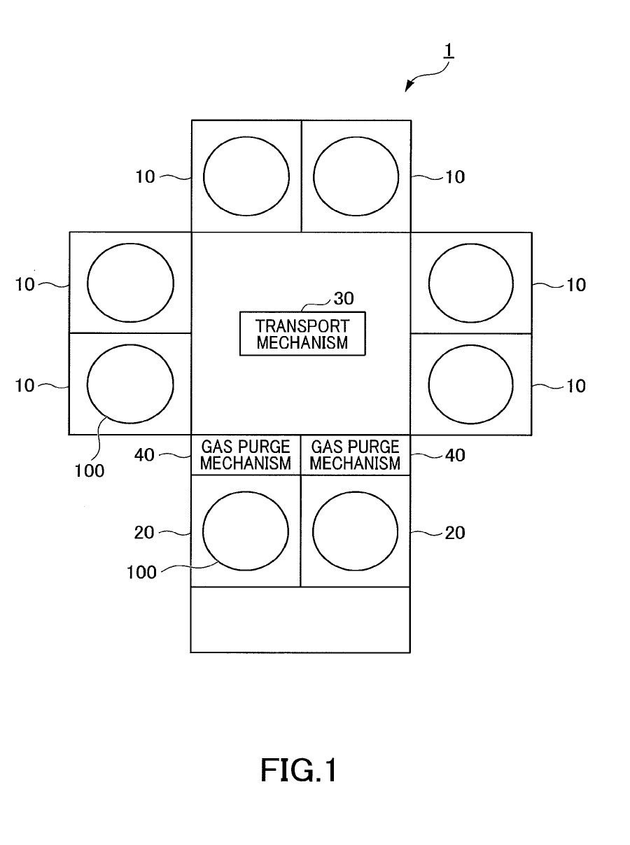

FIG. 1 is a diagram showing a schematic configuration of a semiconductor manufacturing apparatus 1 according to a first embodiment. The semiconductor manufacturing apparatus 1 includes process chambers 10, load lock chambers 20, a transport mechanism 30 and gas purge mechanisms 40.

The process chamber 10 treats a wafer-like substrate 100 using process gas in a vacuum state. For example, the process of the process chamber 10 corresponds to CDE. The load lock chamber 20 temporarily houses the substrate 100 while holding the vacuum state. The transport mechanism 30 transports the substrate 100 between the process chamber 10 and the load lock chamber 20.

In the present embodiment, a plurality of process chambers 10 and a plurality of load lock chambers 20 are provided. Nevertheless, the numbers of the chambers are not specially limited.

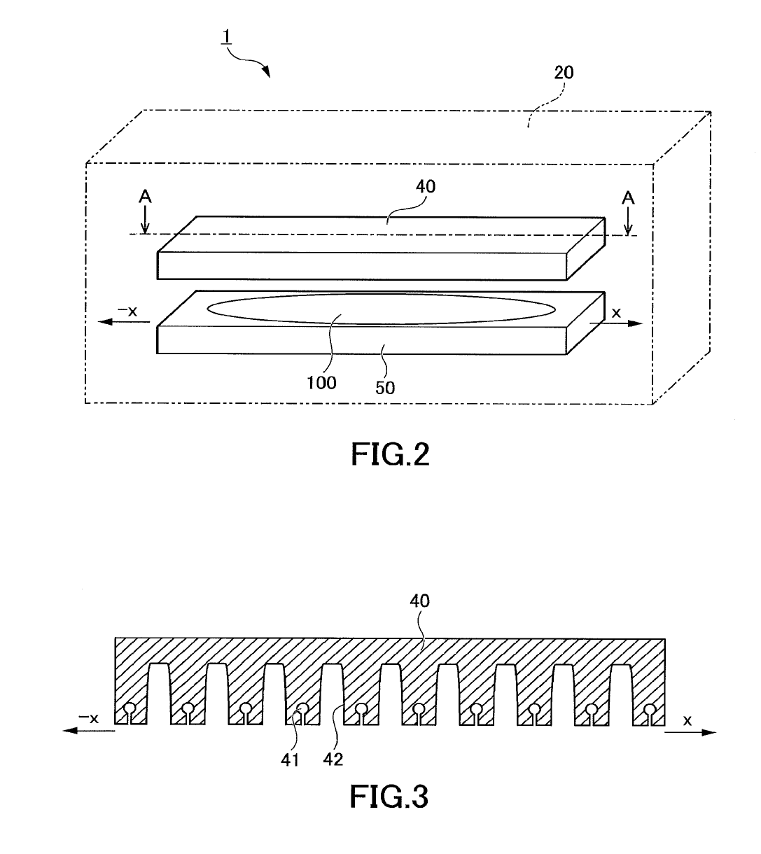

FIG. 2 is a diagram briefly showing the inside of the load lock chamber 20. In the load lock chamber 20, a movement mechanism 50 is below the gas purge mechanism 40. The substrate 100 is retained on the movement mechanism 50. The movement mechanism 50 of the present embodiment is a shake mechanism that shakes (reciprocally moves) in the X-direction and the -X-direction which are parallel to the gas purge mechanism 40. This movement mechanism 50 may be constituted as a part of the transport mechanism 30. Moreover, the X-direction may coincide with the travelling direction of the substrate 100 from the load lock chamber 20 toward the process chamber 10.

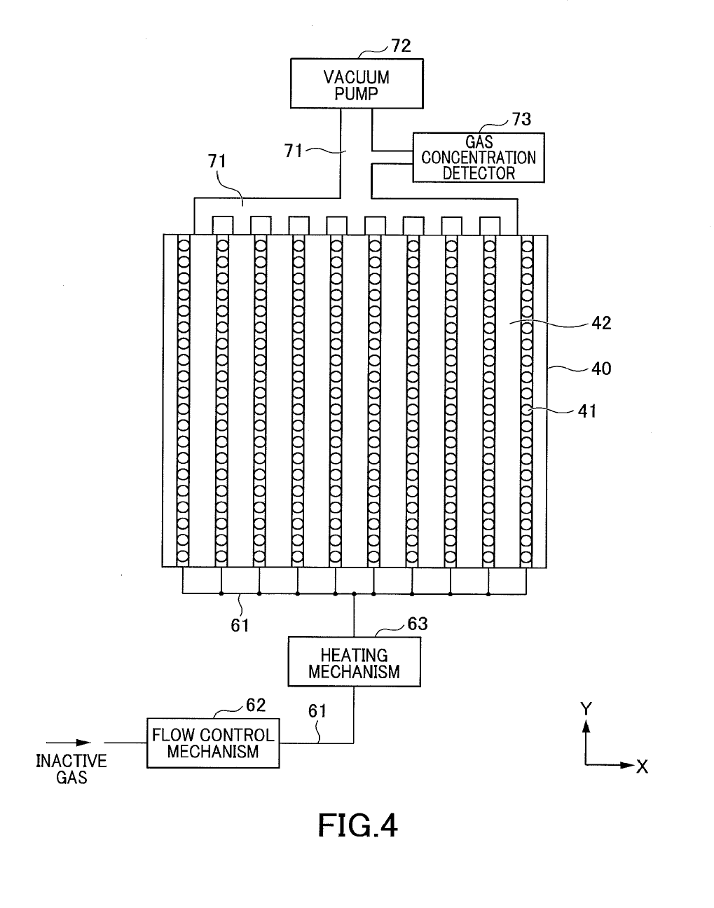

FIG. 3 is a cross-sectional view taken along the sectional line A-A in FIG. 2. FIG. 4 is a view of the gas purge mechanism 40 as seen from its bottom face. As shown in FIG. 3 and FIG. 4, the gas purge mechanism 40 includes a plurality of gas feed ports 41 and a plurality of gas discharge ports 42.

The plurality of gas feed ports 41 eject inactive gas flowing therein from feed channels 61 (see FIG. 4) toward the substrate 100 retained on the movement mechanism 50. In this stage, each gas feed port 41 ejects the inactive gas at a first pressure higher than the atmospheric pressure, for example, a pressure higher than 0.1 MPa. For this inactive gas, for example, nitrogen (N₂) gas, argon (Ar) gas, xenon (Xe) gas or the like is used.

Moreover, as shown in FIG. 4, a flow control mechanism 62 and a heating mechanism 63 are provided on the feed channel 61. The flow control mechanism 62 controls a flow rate of the inactive gas in the feed channel 61. The heating mechanism 63 heats the inactive gas, for example, at a temperature not less than 60 degrees in order to enhance a discharge effect of the gas.

The plurality of gas discharge ports 42 are provided alternately along with the plurality of gas feed ports 41 along the movement direction (X-direction, -X-direction) of the movement mechanism 50. The plurality of gas discharge ports 42 are connected to a vacuum pump 72 and a gas concentration detector 73 via discharge channels 71. The vacuum pump 72 puts the discharge channels 71 in a vacuum state. Thereby, the process gas and the inactive gas are discharged at a second pressure lower than the atmospheric pressure from the gas discharge ports 42. The gas concentration detector 73 detects a concentration of the process gas discharged from the gas discharge ports 42.

Hereafter, operation of the semiconductor manufacturing apparatus 1 according to the present embodiment is described. First, the transport mechanism 30 transports the substrate 100 housed in the load lock chamber 20 into the process chamber 10 (see FIG. 1). The process chamber 10 treats the transported substrate 100 using the process gas in the vacuum state. In the middle of the process or after the process is completed, the transport mechanism 30 takes the substrate 100 out of the process chamber 10 to return it to the load lock chamber 20. Gas sticking to the substrate 100 is removed by the gas purge mechanism 40 and the movement mechanism 50 in the load lock chamber 20.

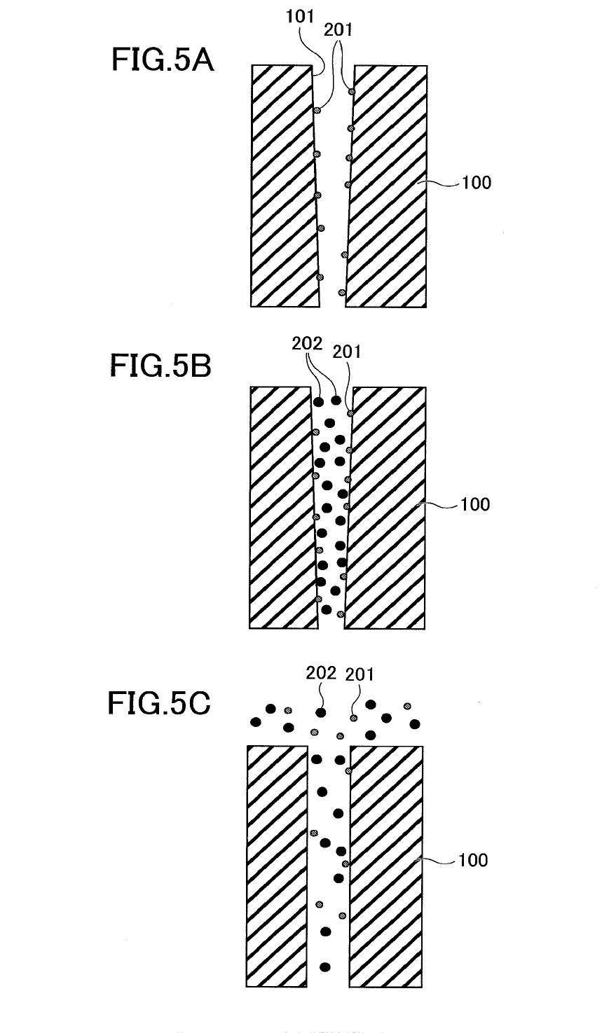

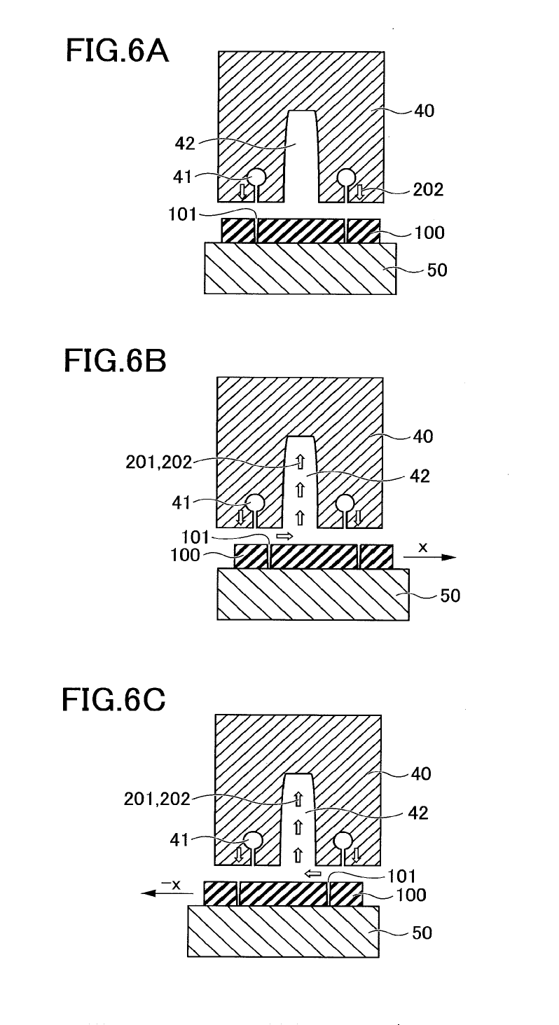

Here, referring to FIG. 5 and FIG. 6, removal mechanism of the gas is described.

FIG. 5A to FIG. 5C are cross-sectional views having a part of the substrate 100 expanded. FIG. 6A to FIG. 6C are cross-sectional views having parts of the gas purge mechanism 40 and the movement mechanism 50 expanded.

As shown in FIG. 5A, the substrate 100 has a slit 101. The slit 101 is formed, for example, for replacing an insulator layer (for example, a silicon nitride film) by an electrode layer (for example, a tungsten film) in production of a three-dimensional memory. By the process of the process chamber 10, particulate process gas 201 sticks onto the inner wall of the slit 101. This process gas 201 may be gas actually used for substrate processing in the process chamber 10, or may be a by-product generated through the substrate processing, for example, ammonium (NH₄).

Subsequently, the substrate 100 is transported into the load lock chamber 20 by the transport mechanism 30 and retained on the movement mechanism 50. In this stage, as shown in FIG. 6A, the slit 101 is positioned closer to the gas feed port 41 than to the gas discharge port 42. When inactive gas 202 is ejected in this state from each gas feed port 41, as shown in FIG. 5B, particulate inactive gas 202 comes into the slit 101. In this stage, since the inactive gas 202 is ejected at a high pressure, a collision number of the inactive gas 202 per unit area on the inner wall of the slit 101 is large. As a result, as shown in FIG. 5C, removal of the process gas 201 is promoted.

After that, as shown in FIG. 6B and FIG. 6C, the movement mechanism 50 shakes in the X-direction and the -X-direction. In accordance with this shake, the slit 101 is displaced closer to the gas discharge port 42 than to the gas feed port 41. In this stage, since each gas discharge port 42 is always put in the vacuum state by the vacuum pump 72, the process gas 201 and the inactive gas 202 are discharged from each gas discharge port 42.

The concentration of the discharged process gas 201 is detected by the gas concentration detector 73. The gas concentration detector 73 displays the detection result. Thereby, a user can confirm the discharge state of the process gas 201.

According to the present embodiment described above, the plurality of gas feed ports 41 in the gas purge mechanism 40 are disposed close to the substrate 100, and the high pressure inactive gas 202 is ejected toward the substrate 100 from the gas feed ports 41. Therefore, even when the whole load lock chamber 20 is not put into a high pressure state, a high pressure region is locally formed. Accordingly, a discharge effect of the process gas 201 and the inactive gas 202 can be enhanced in a short time.

Moreover, in the present embodiment, the movement mechanism 50 shakes the substrate 100, not causing it to travel in one direction. Therefore, a movement range (stroke) of the substrate 100 is limited, which can suppress the device from being upsized.

(Modification 1)

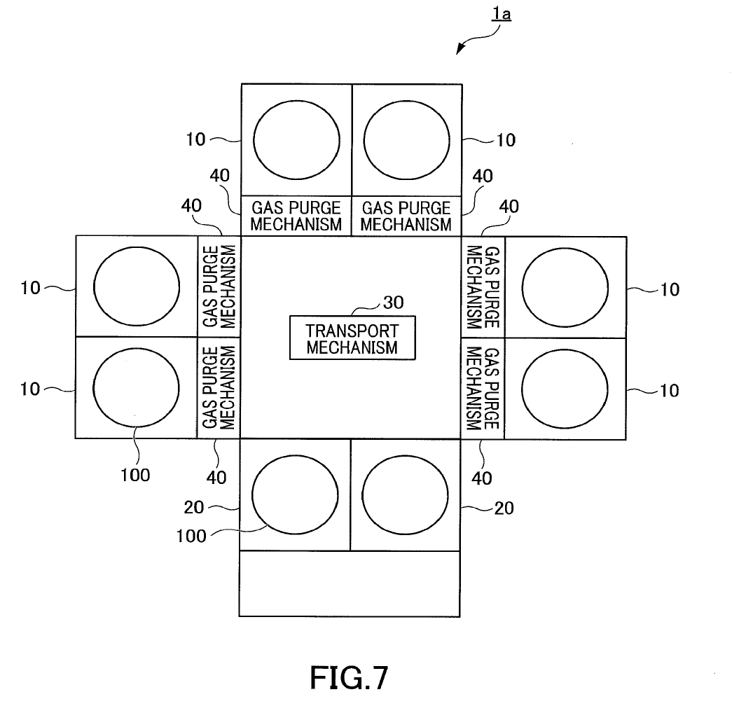

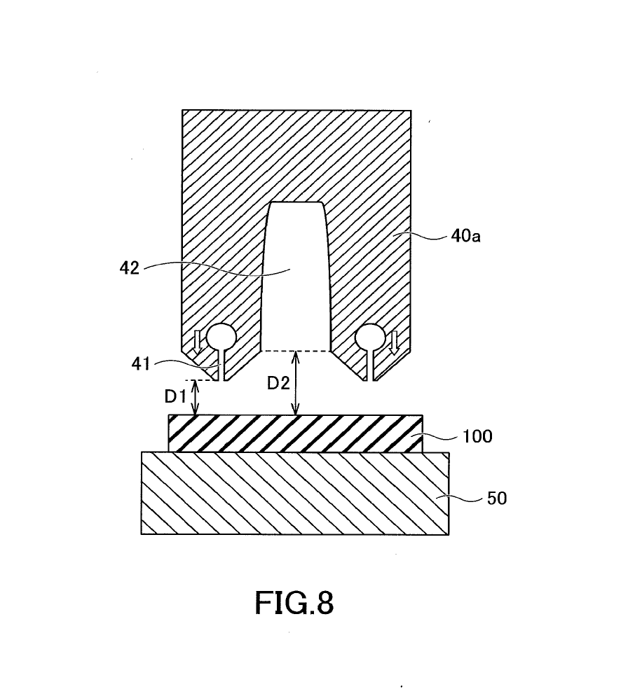

FIG. 7 is a diagram showing a schematic configuration of a semiconductor manufacturing apparatus la according to modification 1. In FIG. 7, the similar constituents to those of the aforementioned semiconductor manufacturing apparatus 1 according to the first embodiment are given the same signs, and their detailed description is omitted.

In the semiconductor manufacturing apparatus la according to the present modification, the aforementioned gas purge mechanisms 40 and movement mechanisms 50 (not shown in FIG. 7) are in the process chambers 10. The configurations and operations of the gas purge mechanism 40 and the movement mechanism 50 are similar to those in the first embodiment.

According to the present modification, it is not needed for the substrate 100 to be once returned to the load lock chamber 20 when discharge is performed by the gas purge mechanism 40 in the middle of the process of the substrate 100. As a result, a time required for the process of the substrate 100 is further shortened, which improves productivity.

(Modification 2)

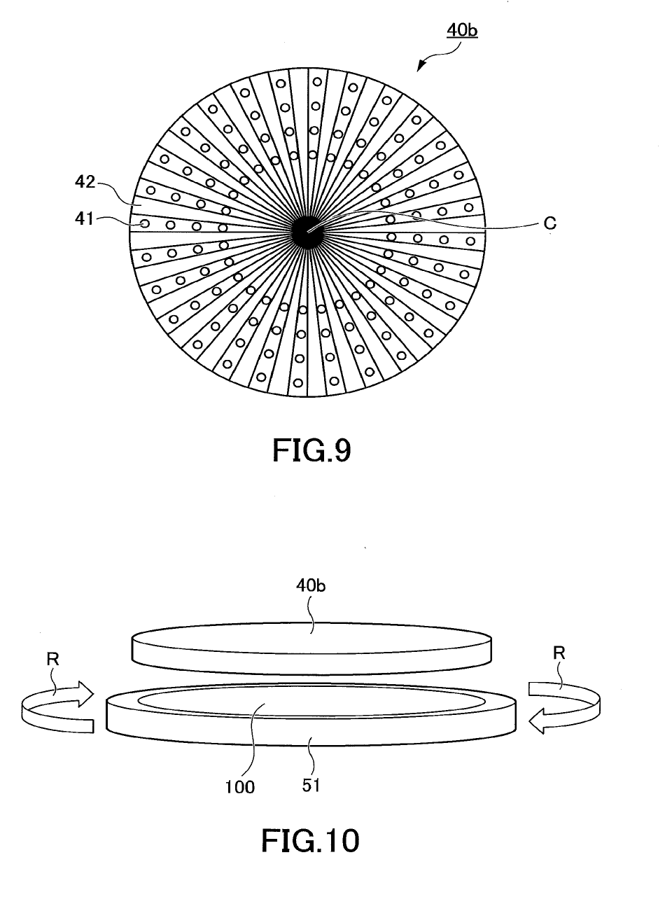

FIG. 8 is a cross-sectional view showing a structure of a gas purge mechanism 40a according to modification 2. In the gas purge mechanism 40a, the gas feed ports 41 protrude toward the movement mechanism 50 side. Meanwhile, the gas discharge ports 42 dent into groove shapes similarly to the first embodiment. Therefore, a distance D1 between the gas feed port 41 and the substrate 100 retained on the movement mechanism 50 is smaller than a distance D2 between the gas discharge port 42 and the relevant substrate 100.

In the gas purge mechanism 40a, while the inactive gas 202 is ejected from the gas feed ports 41, the gas discharge ports 42 are always held in the vacuum state. Therefore, the aforementioned distance D1 is desirably small.

Accordingly, by the gas feed ports 41 protruding as in the present modification, an ejection distance of the inactive gas 202 is shortened. Furthermore, a distance between the gas feed port 41 and the gas discharge port 42 is widen. As a result, higher pressure inactive gas 202 can be fed onto the substrate 100, which further enhances the discharge effect of the process gas 201.

(Modification 3)

FIG. 9 is a diagram showing a view of a gas purge mechanism 40b according to modification 3 as seen from its bottom face. FIG. 10 is a perspective view schematically showing the gas purge mechanism 40b and the movement mechanism 51.

As shown in FIG. 9, the bottom face of the gas purge mechanism 40b is formed to be circular. A plurality of gas feed ports 41 are radially arranged from the center C of the circle. A plurality of gas discharge ports 42 radially extend from the center C. Moreover, the plurality of gas feed ports 41 and the plurality of gas discharge ports 42 are alternately provided along a rotational direction R of the movement mechanism 51.

In the present modification, the movement mechanism 51 is a rotation mechanism that rotationally moves around the aforementioned center C. In accordance with this rotational movement of the movement mechanism 51, ejection of the inactive gas 202 by the gas feed ports 41 and discharge of the process gas 201 and the inactive gas 202 by the gas discharge ports 42 are alternately repeated.

Accordingly, also in the present modification, even when the whole process chamber 10 or the whole load lock chamber 20 is not put into a high pressure state, a high pressure region is locally formed between the substrate 100 and the gas purge mechanism 40. Accordingly, the discharge effect of the process gas 201 and the inactive gas 202 can be enhanced in a short time.

Moreover, in the present modification, since the movement mechanism 51 rotationally moves, the movement range of the substrate 100 is further limited more than that in the first embodiment, which can more suppress the device from being upsized, according to the present modification.

### Second Embodiment

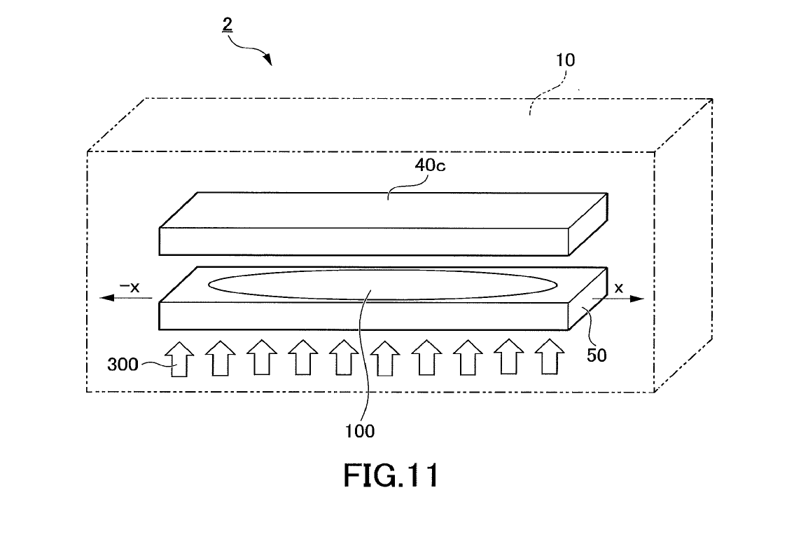

FIG. 11 is a diagram schematically showing a semiconductor manufacturing apparatus according to a second embodiment. In the present embodiment, the similar constituents to those in the first embodiment are given the same signs, and their detailed description is omitted.

A semiconductor manufacturing apparatus 2 according to the present embodiment includes the process chamber 10, a gas purge mechanism 40c and the movement mechanism 50. The semiconductor manufacturing apparatus 2 can be applied, for example, to an ALD film forming device which forms various films, such as channel films, in a memory hole of a three-dimensional memory.

The process chamber 10 houses the gas purge mechanism 40c and the movement mechanism 50. A temperature inside the process chamber 10 is raised with heat 300. In this state, the substrate 100 retained on the movement mechanism 50 is processed.

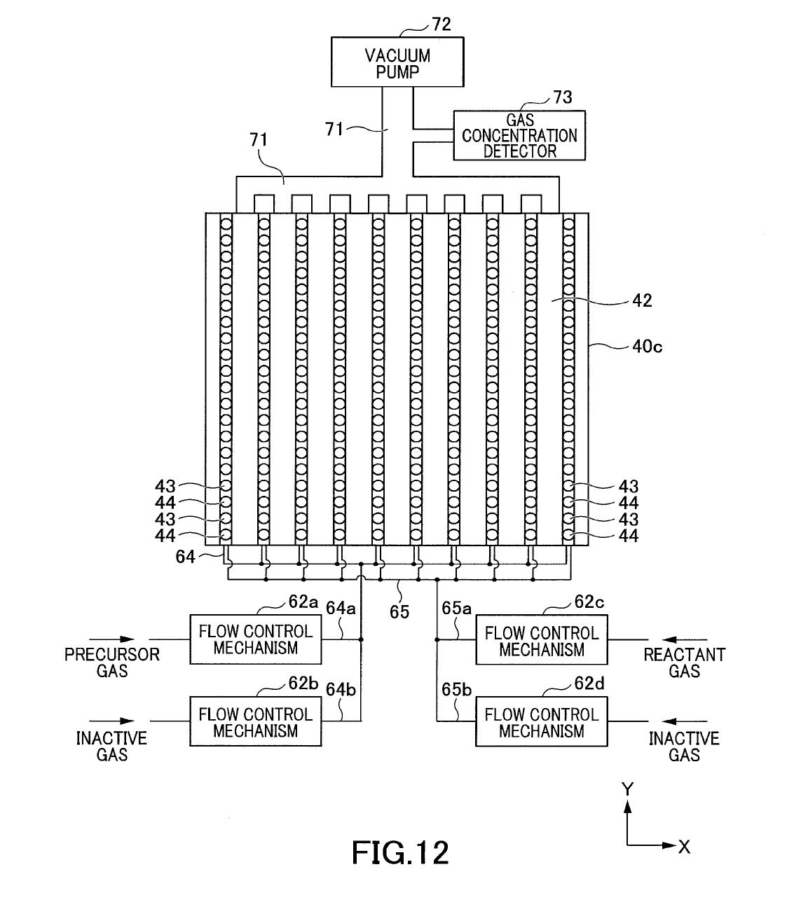

FIG. 12 is a view of the gas purge mechanism 40c as seen from its bottom face. The gas purge mechanism 40c includes the gas discharge ports 42, a plurality of first gas feed ports 43 and a plurality of second gas feed ports 44. Similarly to the first embodiment, the gas discharge ports 42 are connected to the vacuum pump 72 and the gas concentration detector 73 via the discharge channels 71.

The plurality of first gas feed ports 43 and the plurality of second gas feed ports 44 are alternately provided along the Y-direction perpendicular to the movement direction X. The first gas feed ports 43 communicate with first feed channels 64. The upstream side of the first feed channels 64 branches into a feed channel 64a for feeding precursor gas and a feed channel 64b for feeding inactive gas. A flow control mechanism 62a and a flow control mechanism 62b are respectively provided on the feed channel 64a and the feed channel 64b.

The second gas feed ports 44 communicate with second feed channels 65. The upstream side of the second feed channels 65 branches into a feed channel 65a for feeding reactant gas and a feed channel 65b for feeding inactive gas. A flow control mechanism 62c and a flow control mechanism 62d are respectively provided on the feed channel 65a and the feed channel 65b.

Hereafter, operation of the semiconductor manufacturing apparatus 2 according to the present embodiment is described. First, the flow control mechanism 62a causes the first gas feed ports 43 to eject the precursor gas through the first feed channels 64, and simultaneously, the flow control mechanism 62c causes the second gas feed ports 44 to eject the reactant gas through the second feed channels 65. In this stage, the flow control mechanism 62b and the flow control mechanism 62d suspend feed of the inactive gas. The precursor gas and the reactant gas are mixed as process gas for film forming to be deposited on the substrate 100.

After the film forming process is completed, the flow control mechanism 62a suspends the feed of the precursor gas, and simultaneously, the flow control mechanism 62c suspends the feed of the reactant gas. Subsequently, the flow control mechanism 62b and the flow control mechanism 62d start to respectively feed the inactive gas from the first gas feed ports 43 and the second gas feed ports 44 through the first feed channels 64 and the second feed channels 65. In this stage, also in the present embodiment, since the inactive gas is ejected at a high pressure from the first gas feed ports 43 and the second gas feed ports 44, removal of the process gas is promoted.

After that, similarly to the first embodiment, the movement mechanism 50 shakes in the X-direction and the -X-direction which are parallel to the gas purge mechanism 40c. Therefore, the process gas is discharged from the gas discharge ports 42.

According to the present embodiment described above, the first gas feed ports 43 and the second gas feed ports 44 of the gas purge mechanism 40c are disposed close to the substrate 100, and the high pressure inactive gas is ejected toward the substrate 100 from these gas feed ports. Therefore, even when the whole process chamber 10 is not put into a high pressure state, a high pressure region is locally formed. Therefore, the discharge effect of the process gas and the inactive gas can be enhanced in a short time.

Moreover, in the present embodiment, since the gas purge mechanism 40c has feed functions of process gas and inactive gas, the device can be downsized. Furthermore, since the inactive gas flows in the first feed channels 64 and the second feed channels, the precursor gas and the reactant gas sticking to the first gas feed ports 43 and the second gas feed ports 44 can also be removed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor manufacturing apparatus comprising:
a process chamber to treat a substrate using process gas in a vacuum state;
a load lock chamber to temporarily house the substrate while holding the vacuum state;
a gas purge mechanism in the process chamber or the load lock chamber; and
a movement mechanism to retain the substrate below the gas purge mechanism, wherein
the gas purge mechanism includes
a plurality of gas feed ports opposing to the movement mechanism and to eject inactive gas at a first pressure higher than an atmospheric pressure, and
a plurality of gas discharge ports provided alternately along with the plurality of gas feed ports along a movement direction of the movement mechanism and to discharge the process gas and the inactive gas at a second pressure lower than the atmospheric pressure.

2. The semiconductor manufacturing apparatus according to claim 1, wherein the movement mechanism shakes in a direction parallel to the gas purge mechanism.

3. The semiconductor manufacturing apparatus according to claim 1, wherein
the gas purge mechanism includes a circular face on which the gas feed ports and the gas discharge ports are provided, and
the movement mechanism rotationally moves around a center of the circular face.

4. The semiconductor manufacturing apparatus according to claim 1, further comprising a gas concentration detector communicating with the gas discharge ports and to detect a concentration of the process gas discharged from the gas discharge ports.

5. The semiconductor manufacturing apparatus according to claim 1, further comprising:
a feed channel communicating with the plurality of gas feed ports; and
a heating mechanism on the feed channel and to heat the inactive gas.

6. The semiconductor manufacturing apparatus according to claim 1, wherein a distance between the gas feed port and the substrate retained on the movement mechanism is smaller than a distance between the gas discharge port and the substrate.

7. The semiconductor manufacturing apparatus according to claim 6, wherein the gas feed port protrudes toward the movement mechanism side, and the gas discharge port dents into a groove shape.

8. A semiconductor manufacturing apparatus comprising:
a process chamber to treat a substrate using process gas including precursor gas and reactant gas mixed in a vacuum state;
a gas purge mechanism in the process chamber; and
a movement mechanism to retain the substrate below the gas purge mechanism, wherein
the gas purge mechanism includes
first gas feed ports opposing to the movement mechanism and to eject the precursor gas and inactive gas at a first pressure higher than an atmospheric pressure in different timings from each other,
second gas feed ports provided alternately along with the first gas feed ports along a direction perpendicular to a movement direction of the movement mechanism and to eject the reactant gas and the inactive gas in different timings from each other, and
a plurality of gas discharge ports provided alternately along with the first gas feed ports and the second gas feed ports along the movement direction and to discharge the process gas and the inactive gas at a second pressure lower than the atmospheric pressure.
